(19) United States
(12) Patent Application Publication
(10) Pub. No.: US 2013/0164101 A1
(43) Pub. Date: Jun. 27, 2013

(54) ROBOT ARM STRUCTURE AND ROBOT

(71) Applicant: KABUSHIKI KAISHA YASKAWA DENKI, Fukuoka (JP)

(72) Inventors: Tadataka NOGUCHI, Fukuoka (JP); Yuuki OHARA, Fukuoka (JP)

(73) Assignee: KABUSHIKI KAISHA YASKAWA DENKI, Fukuoka (JP)

(21) Appl. No.: 13/670,571

(22) Filed: Nov. 7, 2012

(30) Foreign Application Priority Data
Dec. 21, 2011 (JP) 2011-280376

(51) Int. Cl. H01L 21/677

(52) U.S. Cl. CPC H01L 21/67739; Y10S 901/49
USPC 414/217; 901/49

(57) ABSTRACT

An arm structure of a robot installed in a vacuum chamber kept in a depressurized state includes a first arm, a second arm, and an end effector configured to hold a workpiece. The first arm is provided with a specified drive system arranged in an inside of the first arm, and the inside of the first arm is kept in an atmospheric pressure state. The second arm has no drive system therein. A partition wall is provided near a connecting portion of the first arm and the second arm to isolate the atmospheric pressure state maintained within the first arm from the depressurized state. An airtight terminal is provided in the partition wall to electrically interconnect an atmosphere side and a vacuum side in an airtight state.

### CROSS-REFERENCE TO RELATED APPLICATIONS

The present disclosure contains subject matter related to that disclosed in Japanese Priority Patent Application No. 2011-280376 filed with the Japan Patent Office on Dec. 21, 2011, the entire contents of which are incorporated herein by reference.

### BACKGROUND OF THE INVENTION

1. Field of the Invention

An embodiment disclosed herein relates to a robot arm structure and a robot.

2. Description of the Related Art

Conventionally, there has been known a robot by which a flat workpiece such as a glass substrate for liquid crystal displays or a semiconductor wafer is loaded into and unloaded from a stocker. The robot is installed within a chamber kept in a depressurized state (hereinafter referred to as “vacuum chamber”).

There has been proposed a substrate processing apparatus in which sensors for determining the state of a substrate transferred by a robot are installed in a vacuum chamber (see, e.g., Japanese Patent Application Publication No. 2011-210814).

In the substrate processing apparatus noted above, the sensors for determining the state of the substrate are installed in all the points where the substrate is loaded and unloaded.

In the conventional substrate processing apparatus, however, it is necessary to provide a plurality of sensors. With a view to reduce the apparatus manufacturing cost, there is a room for improvement.

### SUMMARY OF THE INVENTION

In accordance with an aspect of the embodiment, there is provided an arm structure of a robot installed in a vacuum chamber kept in a depressurized state and configured to transfer a workpiece, including: a first arm having a base end portion rotatably connected to an arm base of the robot, the first arm including a specified drive system arranged in an inside of the first arm, the inside of the first arm being kept in an atmospheric pressure state; a second arm having a base end portion rotatably connected to a tip end portion of the first arm, the second arm including no drive system therein; an end effector rotatably connected to a tip end portion of the second arm through a movable base and configured to hold the workpiece; a partition wall provided near a connecting portion of the first arm and the second arm to isolate the atmospheric pressure state maintained within the first arm from the depressurized state; and an airtight terminal provided in the partition wall to electrically interconnect an atmosphere side and a vacuum side in an airtight state.

### BRIEF DESCRIPTION OF THE DRAWINGS

FIG. 1 is a schematic perspective view showing a robot according to the present embodiment.

FIG. 2 is a schematic side view showing the robot installed within a vacuum chamber.

FIG. 3A is a first schematic diagram showing the state of a cable.

FIG. 3B is a second schematic diagram showing the state of a cable.

FIG. 4 is a schematic side view for explaining an airtight terminal.

FIG. 5 is a schematic side view illustrating an airtight terminal according to a modified example.

### DESCRIPTION OF THE EMBODIMENTS

One embodiment of a robot arm structure and a robot disclosed herein will now be described with reference to the accompanying drawings. The robot arm structure and the robot are not limited to the embodiment to be described below.

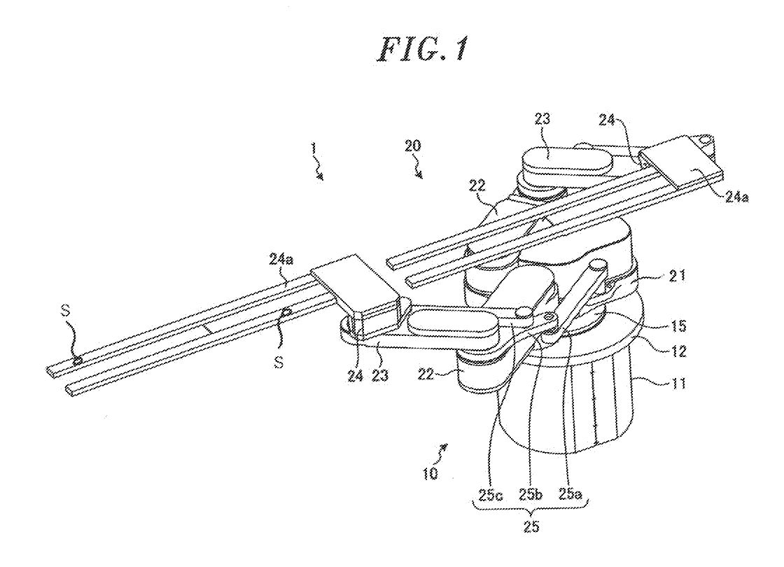

First, the configuration of a robot according to the present embodiment will be described with reference to FIG. 1. FIG. 1 is a schematic perspective view showing a robot according to the present embodiment.

As shown in FIG. 1, the robot 1 is a horizontal articulated robot including two extendible arm units that can extend and retract in a horizontal direction. More specifically, the robot 1 includes a body unit 10 and an arm unit 20.

The body unit 10 is a unit provided below the arm unit 20. The body unit 10 includes a tubular housing 11 and a lifting device arranged within the housing 11. The body unit 10 moves the arm unit 20 up and down in a vertical direction using the lifting device.

The lifting device is configured to include, e.g., a motor, a ball screw and a ball nut. The lifting device moves a lifting flange unit 15 up and down in the vertical direction by converting the rotating motion of the motor to a linear motion. As a consequence, the arm unit 20 fixed on the lifting flange unit 15 is moved up and down.

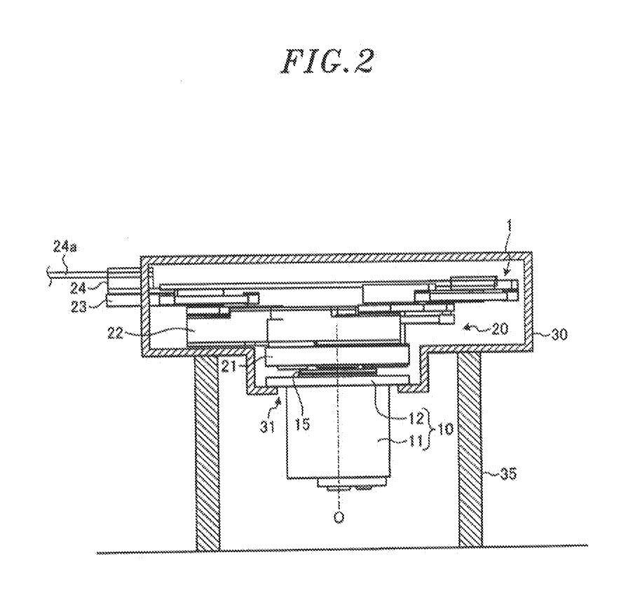

A flange portion 12 is formed in the upper portion of the housing 11. The robot 1 is installed in a vacuum chamber by fixing the flange portion 12 to the vacuum chamber. On this point, description will be made later with reference to FIG. 2.

The arm unit 20 is a unit connected to the body unit 10 through the lifting flange unit 15. More specifically, the arm unit 20 includes an arm base 21, a first arm 22, a second arm 23, a movable base 24 and an auxiliary arm 25.

The robot 1 according to the present embodiment is a dual arm robot including two sets of extendible arm units, each of which has the first arm 22, the second arm 23, the movable base 24 and the auxiliary arm 25.

However, the present disclosure is not limited to the above. The robot 1 may be a single arm robot including one extendible arm unit or a robot including three or more extendible arm units.

The arm base 21 is rotatably supported with respect to the lifting flange unit 15. The arm base 21 includes a swing device made up of a motor and a speed reducer. The arm base 21 is swung by the swing device.

More specifically, the swing device is configured such that the rotation of the motor is inputted via a transmission belt to the speed reducer whose output shaft is fixed to the body unit 10. Thus the arm base 21 horizontally revolves on its own axis using the output shaft of the speed reducer as a swing axis.

The arm base 21 includes a box-shaped storage compartment kept at the atmospheric pressure. The motor, the speed reducer and the transmission belt are stored within the storage compartment. Therefore, even if the robot 1 is used within a vacuum chamber as described later, it is possible to prevent a lubricant such as grease or the like from getting dry and to prevent the inside of the vacuum chamber from being contaminated by dirt.

The base end portion of the first arm 22 is rotatably connected to the upper portion of the arm base 21 through a first speed reducer to be described later. The first arm 22 includes a box-shaped storage compartment kept at the atmospheric pressure. The base end portion of the second arm 23 is rotatably connected to the tip end upper portion of the first arm 22 through a second speed reducer to be described later. Unlike the arm base 21, the second arm 23 as a whole is exposed to a vacuum environment.

The movable base 24 is rotatably connected to the tip end portion of the second arm 23. The movable base 24 is provided at an upper end thereof with an end effector 24a for holding a thin flat workpiece. The movable base 24 linearly moves in response to the rotating motion of the first arm 22 and the second arm 23. In the following description, the thin flat workpiece will be just referred to as substrate. The substrate may be a glass substrate for liquid crystal displays or a semiconductor wafer.

In the conventional case, when transferring the substrate, the presence or absence of the substrate is determined by sensors provided within a vacuum chamber. In the conventional case, it is necessary to provide the sensors in all the points within the vacuum chamber where the substrate is loaded and unloaded. Thus the apparatus becomes expensive.

The presence or absence of the substrate is determined in a state that the second arm 23 comes back to the positions where the sensors are arranged. In case of the dual arm robot shown in FIG. 1, a pair of end effectors 24a may be in a vertically overlapping state.

For that reason, when determining the presence or absence of the substrate, the conventional robot cannot determine whether the substrate is placed on an upper end effector 24a or on a lower end effector 24a.

In the robot 1 according to the present embodiment, sensors S for detecting the presence or absence of the substrate are arranged in each of the end effectors 24a. In the robot 1 according to the present embodiment, it is therefore possible to reduce the apparatus manufacturing cost and to accurately determine on which end effector 24a the substrate is placed.

In the robot 1 according to the present embodiment, the sensors S can detect the presence or absence of the substrate at the moment when the substrate is placed on each of the end effectors 24a. It is therefore possible to prevent the substrate from being dropped as the substrate is transferred in an unstable state due to a misalignment.

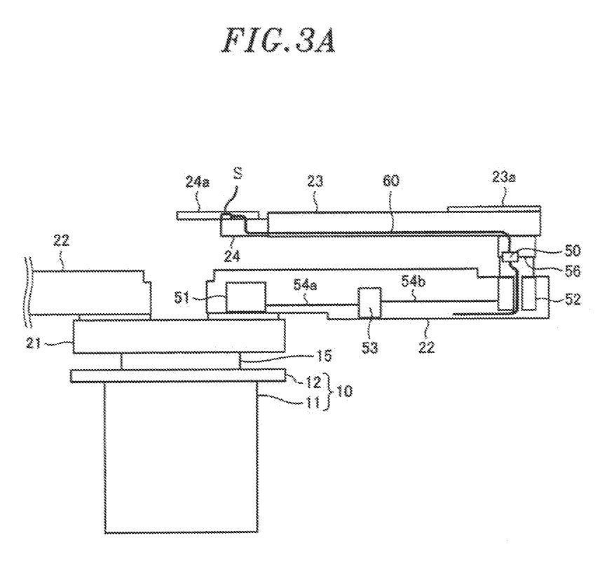

The robot 1 supplies an electric current to the sensors S by way of a cable 60 (see FIG. 3A) arranged within the first arm 22 and the second arm 23. Details on the arrangement of the cable 60 will be described later with reference to FIGS. 3A and 3B.

The robot 1 linearly moves the end effector 24a by synchronously operating the first arm 22 and the second arm 23. More specifically, the robot 1 rotates the first speed reducer and the second speed reducer through the use of a single motor, thereby synchronously operating the first arm 22 and the second arm 23.

The robot 1 rotates the first arm 22 and the second arm 23 such that the rotation amount of the second arm 23 with respect to the first arm 22 becomes twice as large as the rotation amount of the first arm 22 with respect to the arm base 21.

For example, the robot 1 rotates the first arm 22 and the second arm 23 in such a way that, if the first arm 22 rotates a degree with respect to the arm base 21, the second arm 23 rotates 2α degrees with respect to the first arm 22. As a consequence, the robot 1 can linearly move the end effector 24a.

With a view to prevent contamination of the inside of the vacuum chamber, drive devices such as the first speed reducer, the second speed reducer, the motor and the transmission belt are arranged within the first arm 22 kept at the atmospheric pressure.

The auxiliary arm 25 is a link mechanism that restrains rotation of the movable base 24 in conjunction with the rotating motion of the first arm 22 and the second arm 23 so that the end effector 24a is always directed to a specified direction during its movement.

More specifically, the auxiliary arm 25 includes a first link 25a, an intermediate link 25b and a second link 25c.

The base end portion of the first link 25a is rotatably connected to the arm base 21. The tip end portion of the first link 25a is rotatably connected to the tip end portion of the intermediate link 25b. The base end portion of the intermediate link 25b is pivoted in a coaxial relationship with a connecting axis that interconnects the first arm 22 and the second arm 23. The tip end portion of the intermediate link 25b is rotatably connected to the tip end portion of the first link 25a.

The base end portion of the second link 25c is rotatably connected to the intermediate link 25b. The tip end portion of the second link 25c is rotatably connected to the base end portion of the movable base 24. The tip end portion of the movable base 24 is rotatably connected to the tip end portion of the second arm 23. The base end portion of the movable base 24 is rotatably connected to the second link 25c.

The first link 25a, the arm base 21, the first arm 22 and the intermediate link 25b make up a first parallel link mechanism. In other words, if the first arm 22 rotates about the base end portion thereof, the first link 25a rotates while keeping parallelism with the first arm 22. When seen in a plan view, the intermediate link 25b rotates while keeping parallelism with an imaginary connecting line that interconnects the connecting axis of the arm base 21 and the first arm 22 and the connecting axis of the arm base 21 and the first link 25a.

The second link 25c, the second arm 23, the movable base 24 and the intermediate link 25b make up a second parallel link mechanism. In other words, if the second arm 23 rotates about the base end portion thereof, the second link 25c and the movable base 24 rotate while keeping parallelism with the second arm 23 and the intermediate link 25b, respectively.

The intermediate link 25b rotates while keeping parallelism with the aforementioned connecting line under the action of the first parallel link mechanism. For that reason, the movable base 24 of the second parallel link mechanism rotates while keeping parallelism with the aforementioned connecting line. As a result, the end effector 24a mounted to the upper portion of the movable base 24 moves linearly while keeping parallelism with the aforementioned connecting line.

In the robot 1, the rigidity of the arm unit as a whole can be increased by the auxiliary arm 25. It is therefore possible to reduce the vibration generated during the operation of the end effector 24a. This makes it possible to suppress generation of dirt attributable to the vibration generated during the operation of the end effector 24a.

The robot 1 according to the present embodiment includes two sets of extendible arm units, each of which includes the first arm 22, the second arm 23, the movable base 24 and the auxiliary arm 25. Therefore, the robot 1 can simultaneously perform two tasks, e.g., a task of taking out a substrate from a specified transfer position using one of the extendible arm units and a task of carrying a new workpiece into the transfer position using the other extendible arm unit.

Next, the robot 1 installed within the vacuum chamber will be described with reference to FIG. 2. FIG. 2 is a schematic side view showing the robot 1 installed within the vacuum chamber.

As shown in FIG. 2, the flange portion 12 provided to the body unit 10 of the robot 1 is fixed through a seal member to the peripheral edge of an opening portion 31 formed in the bottom of the vacuum chamber 30. Thus the vacuum chamber 30 is hermetically sealed and the inside of the vacuum chamber 30 is kept in a depressurized state by a depressurizing device such as a vacuum pump or the like. The housing 11 of the body unit 10 protrudes from the bottom of the vacuum chamber 30 and lies within a space defined by a support portion 35 which supports the vacuum chamber 30.

The robot 1 performs a substrate transferring task within the vacuum chamber 30. For example, the robot 1 linearly moves the end effector 24a through the use of the first arm 22 and the second arm 23, thereby taking out a substrate from another vacuum chamber connected to the vacuum chamber 30 through a gate valve (not shown).

Subsequently, the robot 1 returns the end effector 24a back and then horizontally rotates the arm base 21 about a swing axis O, thereby causing the arm unit 20 to directly face another vacuum chamber as the transfer destination of the substrate. Then, the robot 1 linearly moves the end effector 24a through the use of the first arm 22 and the second arm 23, thereby carrying the substrate into the another vacuum chamber as the transfer destination of the substrate.

The vacuum chamber 30 is formed in conformity with the shape of the robot 1. For example, as shown in FIG. 2, a recess portion is formed in the bottom surface portion of the vacuum chamber 30. The portions of the robot 1 such as the arm base 21 and the lifting flange unit 15 are arranged in the recess portion. By forming the vacuum chamber 30 in conformity with the shape of the robot 1 in this manner, it is possible to reduce the internal volume of the vacuum chamber 30 and to readily keep the vacuum chamber 30 in a depressurized state.

Next, details of the arrangement of the signal lines and the power supply line (hereinafter just referred to as “cable”) of the sensor S will be described with reference to FIGS. 3A and 3B. FIGS. 3A and 3B are schematic side views showing the state of the cable 60.

Referring first to FIG. 3A, the cable 60 is connected to the sensor S provided in the end effector 24a. The cable 60 is arranged within the second arm 23 through a connecting portion where the movable base 24 is connected to the tip end portion of the second arm 23.

The cable 60 is connected, on a line-by-line basis, to an airtight terminal 50 provided in a connecting portion where the first arm 22 and the second arm 23 are connected to each other.

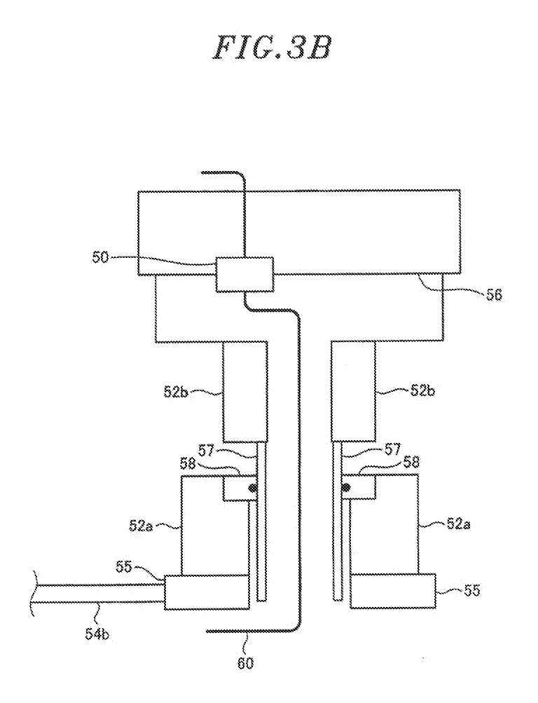

The airtight terminal 50 is a connector provided in a partition wall 56 existing between the second arm 23 kept in a depressurized state and the first arm 22 kept at the atmospheric pressure. The airtight terminal 50 is configured to isolate the first arm 22 and the second arm 23 from each other and to electrically connect the cable 60 between the two different atmospheres. Accordingly, even if the hollow drive shaft of the second speed reducer 52 is rotated, it is possible to keep the airtightness between the insides of the second arm 23 and the second speed reducer 52. Details of the airtight terminal 50 will be described later with reference to FIG. 4.

The cable 60 connected to the airtight terminal 50 extends into the first arm 22 through the hollow region of the hollow drive shaft of the second speed reducer 52. Then, the cable 60 extends to the arm base 21 through the rotating shaft center of the base end portion of the first arm 22 (not shown).

Details of the hollow region of the hollow drive shaft of the second speed reducer 52 will now be described with reference to FIG. 3B.

As shown in FIG. 3B, the upper end portion of a tubular protection pipe 57 is fixed to an output shaft 52b of the second speed reducer 52. The protection pipe 57 is connected to the second arm 23 through the output shaft 52b of the second speed reducer 52 so that the protection pipe 57 can rotate with respect to the first arm 22.

The protection pipe 57 is rotatably supported by an oil seal 58 provided at the middle inner side of the second speed reducer 52. The second speed reducer 52 includes an input shaft 52a and the output shaft 52b which are rotatably connected to each other by speed reducing gears (not shown).

The protection pipe 57 does not make contact with the inner wall of a hollow drive shaft of a pulley 55 and the inner wall of the input shaft 52a. The hollow drive shaft of the pulley 55 is rotatably connected to the input shaft 52a of the second speed reducer 52.

Thus the protection pipe 57 extends so as to pass through the input shaft 52a of the second speed reducer 52 in a contactless manner. The cable 60 connected to the airtight terminal 50 extends into the first arm 22 through the hollow region of the output shaft 52b of the second speed reducer 52 and the hollow region of the protection pipe 57.

In the robot 1 according to the present embodiment, the cable 60 is arranged to pass through the hollow regions of the output shaft 52b of the second speed reducer 52 and the protection pipe 57 which rotate together with the second arm 23.

Accordingly, the robot 1 according to the present embodiment can prevent the cable 60 from making frictional contact with the input shaft 52a of the second speed reducer 52 and the pulley 55, both of which are rotating at a high speed. The cable 60 is safely arranged without getting entangled.

Referring back to FIG. 3A, a motor 53 is provided within the first arm 22. A first speed reducer 51 is arranged in the base end portion of the first arm 22. The second speed reducer 52 is arranged in the tip end portion of the first arm 22. Transmission belts 54a and 54b are respectively provided between the first speed reducer 51 and the motor 53 and between the second speed reducer 52 and the motor 53.

The transmission belt 54a for transmitting the drive power of the motor 53 to the input shaft of the first speed reducer 51 and the transmission belt 54b for transmitting the drive power of the motor 53 to the input shaft of the second speed reducer 52 are wound around the output shaft of the motor 53, whereby the drive power of the motor 53 is transmitted to the first speed reducer 51 and the second speed reducer 52.

As set forth above, the drive devices such as the first speed reducer 51, the second speed reducer 52, the motor 53 and the transmission belts 54a and 54b are arranged within the first arm 22 kept at the atmospheric pressure. In addition, the robot 1 is used within the vacuum chamber 30.

For that reason, the first arm 22 needs to be kept airtight in order to maintain the inside of the vacuum chamber 30 in a depressurized state. Thus the first arm 22 is formed thicker than the second arm 23 and the auxiliary arm 25.

Since the first arm 22 is formed thicker than the second arm 23 and the auxiliary arm 25 and is kept highly airtight, it is possible to prevent a lubricant such as grease or the like from getting dry even when the robot 1 is used within the vacuum chamber 30. Moreover, the robot 1 can prevent the inside of the second arm 23 and the inside of the vacuum chamber 30 from being contaminated with the dirt generated by the drive devices arranged within the first arm 22.

In the robot 1 described above, the cable 60 is not arranged in the auxiliary arm 25 but is arranged in the first arm 22 and the second arm 23. This eliminates the need to arrange the cable 60 in a narrow space within the auxiliary arm 25 exposed to a depressurized environment. In addition, the robot 1 can restrain a gas from being emitted from the auxiliary arm 25 and the cable 60.

A cover 23a is provided on the upper surface of the base end portion of the second arm 23. By removing the cover 23a, a user can perform a maintenance work with respect to the airtight terminal 50 and the cable 60.

Next, details of the airtight terminal 50 will be described with reference to FIG. 4. FIG. 4 is a schematic side view for explaining the airtight terminal 50.

As shown in FIG. 4, the airtight terminal 50 is provided between a space kept in a depressurized state (hereinafter referred to as “vacuum side”) and a space kept at the atmospheric pressure (hereinafter referred to as “atmosphere side”). The airtight terminal 50 is arranged in a hole of the partition wall 56 in a highly airtight manner. In the following description, the upper side of the airtight terminal 50 will be referred to as vacuum side 101 and the lower side of the airtight terminal 50 will be referred to as atmosphere side 102.

For example, as shown in FIG. 4, the airtight terminal is fixed to the partition wall 56 by bolts through a sealant. In an effort to increase the air-tightness, an O-ring (not shown) may be interposed between the partition wall 56 and the airtight terminal 50.

The airtight terminal 50 includes pins 50a and 50b arranged at the vacuum side 101 and the atmosphere side 102. The respective pins 50a and 50b correspond to the signal lines and the power supply line of the sensor S. The respective pins 50a and 50b are electrically connected to one another in between the vacuum side 101 and the atmosphere side 102. While the airtight terminal 50 disclosed herein is of a three-pin type, the number of pins depends on the number of lines included in the cable 60.

Recess portions are formed in a cable terminal 60a provided at the tip end of the cable 60. The pins 50b can be fitted to the recess portions by pushing the cable terminal 60a toward the pins 50b of the airtight terminal 50 (in the direction indicated by the arrow in FIG. 4).

By providing the airtight terminal 50 in the partition wall 56 between the second arm 23 exposed to the depressurized environment and the first arm 22 kept at the atmospheric pressure, it is possible to keep the airtightness between the inside of the second arm 23 and the inside of the second speed reducer 52.

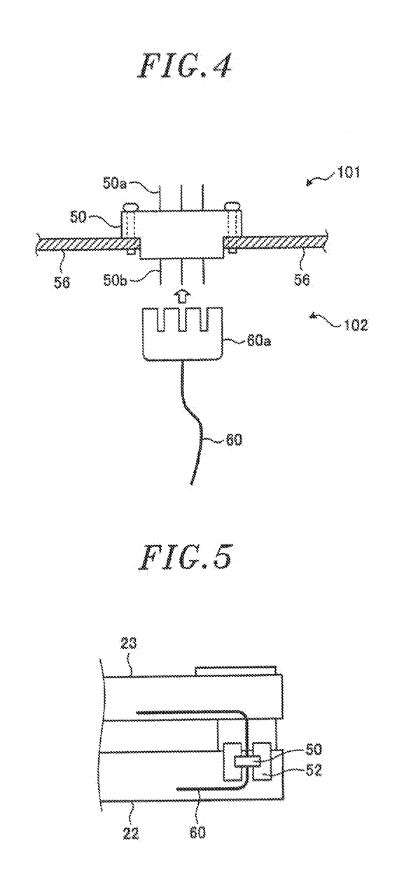

While the airtight terminal 50 is provided in the region within the connecting portion of the second arm 23 and the second speed reducer 52, the present disclosure is not limited thereto. The airtight terminal 50 may be provided in any place where the airtightness between the inside of the second arm 23 and the inside of the second speed reducer 52 can be kept. For example, as shown in FIG. 5, the airtight terminal 50 may be provided in the hollow region of the hollow drive shaft of the second speed reducer 52.

In the robot according to the present embodiment, as described above, the airtight terminal is provided in the partition wall formed in the connecting portion of the first arm and the second arm. The cable is arranged to pass through the hollow region of the hollow drive shaft of the second speed reducer. In the robot according to the present embodiment, the cable is prevented from making frictional contact with the input shaft of the second speed reducer rotating at a high speed. The cable is safely arranged without getting entangled.

In the present embodiment, the sensor for detecting the presence or absence of the substrate is provided in the end effector. This makes it possible to reduce the apparatus manufacturing cost and to determine the presence or absence of the substrate at the moment when the substrate is placed on the end effector.

Other effects and other modified examples can be readily derived by those skilled in the art. For that reason, the broad aspect of the present disclosure is not limited to the specific disclosure and the representative embodiment shown and described above. Accordingly, the present disclosure can be modified in many different forms without departing from the spirit and scope defined by the appended claims and the equivalents thereof.

What is claimed is:

1. An arm structure of a robot installed in a vacuum chamber kept in a depressurized state and configured to transfer a workpiece, comprising:
a first arm having a base end portion rotatably connected to an arm base of the robot, the first arm including a specified drive system arranged in an inside of the first arm, the inside of the first arm being kept in an atmospheric pressure state;
a second arm having a base end portion rotatably connected to a tip end portion of the first arm, the second arm including no drive system therein;
an end effector rotatably connected to a tip end portion of the second arm through a movable base and configured to hold the workpiece;
a partition wall provided near a connecting portion of the first arm and the second arm to isolate the atmospheric pressure state maintained within the first arm from the depressurized state; and
an airtight terminal provided in the partition wall to electrically interconnect an atmosphere side and a vacuum side in an airtight state.

2. The arm structure of claim 1, wherein the first arm includes a speed reducer having a hollow drive shaft for driving the second arm, the partition wall is provided in a hollow region of the hollow drive shaft of the speed reducer or in a closed space near the second arm communicating with the hollow region, and a cable extending in the first arm is connected to the airtight terminal via the hollow region.

3. The arm structure of claim 1, wherein the end effector includes a sensor having a cable connected to the airtight terminal via the second arm.

4. The arm structure of claim 2, wherein the end effector includes a sensor having a cable connected to the airtight terminal via the second arm.

5. The arm structure of claim 2, further comprising:
an intermediate link provided to be rotatable about an axis coaxial with the hollow drive shaft of the speed reducer;
a first link making up a first parallel link mechanism in cooperation with the first arm, the intermediate link and the arm base; and
a second link making up a second parallel link mechanism in cooperation with the second arm, the intermediate link and the movable base.

6. The arm structure of claim 4, further comprising:
an intermediate link provided to be rotatable about an axis coaxial with the hollow drive shaft of the speed reducer;
a first link making up a first parallel link mechanism in cooperation with the first arm, the intermediate link and the arm base; and
a second link making up a second parallel link mechanism in cooperation with the second arm, the intermediate link and the movable base.

7. The arm structure of claim 5, wherein the first arm and the second arm are formed thicker than the first link and the second link.

8. The arm structure of claim 6, wherein the first arm and the second arm are formed thicker than the first link and the second link.

9. The arm structure of claim 2, further comprising:
a protection pipe fixed to an inner wall of the hollow drive shaft of the speed reducer, the protection pipe extending to pass through a hollow region of a hollow input shaft arranged within the speed reducer in a coaxial relationship with the hollow drive shaft without making contact with the input shaft.

10. The arm structure of claim 4, further comprising:
a protection pipe fixed to an inner wall of the hollow drive shaft of the speed reducer, the protection pipe extending to pass through a hollow region of a hollow input shaft arranged within the speed reducer in a coaxial relationship with the hollow drive shaft without making contact with the input shaft.

11. The arm structure of claim 5, further comprising:
a protection pipe fixed to an inner wall of the hollow drive shaft of the speed reducer, the protection pipe extending to pass through a hollow region of a hollow input shaft arranged within the speed reducer in a coaxial relationship with the hollow drive shaft without making contact with the input shaft.

12. The arm structure of claim 6, further comprising:
a protection pipe fixed to an inner wall of the hollow drive shaft of the speed reducer, the protection pipe extending to pass through a hollow region of a hollow input shaft arranged within the speed reducer in a coaxial relationship with the hollow drive shaft without making contact with the input shaft.

13. A robot comprising the arm structure of claim 1.

14. A robot comprising the arm structure of claim 2.

15. A robot comprising the arm structure of claim 3.

16. A robot comprising the arm structure of claim 4.

17. The robot of claim 13, wherein the arm base includes a swing unit configured to swing about a swing axis extending in a vertical direction.

18. The robot of claim 14, wherein the arm base includes a swing unit configured to swing about a swing axis extending in a vertical direction.

19. The robot of claim 15, wherein the arm base includes a swing unit configured to swing about a swing axis extending in a vertical direction.

20. The robot of claim 16, wherein the arm base includes a swing unit configured to swing about a swing axis extending in a vertical direction.
